(19) United States
(12) Patent Application Publication
(10) Pub. No.: US 2005/0020007 A1
(43) Pub. Date: Jan. 27, 2005

(54) Semiconductor element and method for its production

(76) Inventors: Heribert Weber, Nuertingen (DE); Christoph Schelling, Reutlingen (DE)

Correspondence Address: KENYON & KENYON, ONE BROADWAY, NEW YORK, NY, 10004, US

(21) Appl. No.: 10/868,602

(22) Filed: Jun. 14, 2004

(30) Foreign Application Priority Data
Jun. 13, 2003 (DE) 103 26 787.5

(51) Int. Cl. H01L 21/8234

(52) U.S. Cl. 438/238

(57) ABSTRACT

A method of producing conducting tracks and resistors in a semiconductor element that includes at least one conductive layer. The conductive layer is regionally through-oxidized so that at least one region of the conductive layer is electrically insulated by the oxidized regions with respect to the remaining regions of the conductive layer.

### FIELD OF THE INVENTION

The present invention relates to a semiconductor element having at least one conductive layer in which at least one conducting track and/or at least one resistor is/are configured and to a method for producing such a semiconductor element.

### BACKGROUND INFORMATION

To produce conducting tracks and resistors on semiconductor elements, a conductive layer is typically first created on the surface of the semiconductor element. In this context, the conductive layer may be a thin metal layer, e.g. of aluminum, nickel, platinum, or gold, or also a polycrystalline or monocrystalline silicon layer. The desired configuration of conducting tracks and resistors is then structured out of this conductive layer using photolithographic and etching processes. This configuration is then electrically insulated by depositing of an insulator, e.g., silicon oxide SiO₂.

Furthermore, a conventional method for locally oxidizing silicon layers “LOCOS” (local oxidation of silicon) may be used, for example, in the production of microchips with MOS transistors in order to generate a field oxide region in the vicinity of the gate oxide.

### SUMMARY

The present invention may provide a new possibility for producing conducting tracks and resistors in a semiconductor element.

According to an example embodiment of the present invention, the conductive layer of the semiconductor element is regionally through-oxidized so that at least one region of the conductive layer, namely the configuration of the conducting tracks and resistors, is electrically insulated by the oxidized regions with respect to the remaining regions of the conductive layer.

In accordance with the present invention, it was determined that the LOCOS method is also suitable for producing conducting track and resistor configurations in a conductive layer since in this method individual regions of the conductive layer are able to be through-oxidized in a targeted manner so that they are electrically insulated with respect to the remaining regions of the conductive layer. It may be particularly advantageous that this method also allows conducting tracks and resistors to be generated on or in thin, poor heat-conducting membranes, e.g., for producing heater structures and piezo resistors. In this case, the thick oxide regions advantageously contribute to the stability of the membrane and also result in effective heat insulation.

In general, there are different possibilities for producing the semiconductor element of the present invention, in particular with regard to the structure of the conductive layer. It may be important for the material of the conductive layer to able to be through-oxidized and for the resulting oxide to form an effective electric insulator.

In an advantageous variation, a polycrystalline silicon layer is used as the conductive layer. Polycrystalline silicon layers may be produced in a particularly simple manner using methods known from semiconductor technology. Alternatively to a polycrystalline silicon layer, a monocrystalline silicon layer may also be used as the conductive layer. In this variation, the component may be advantageously realized using an SOI (silicon on insulator) wafer. SOI wafers include a substrate on which at least one insulator layer is disposed. Located above this is a thin monocrystalline silicon layer in which a configuration of conducting tracks and resistors may be formed in a particularly simple manner using the method of the present invention. In addition, silicon layers may be provided prior to or following local oxidation with a p- and/or n-doping with any doping material concentration and doping material depth, which proves to be advantageous particularly for electric dimensioning of resistors. In this context, the doping material may be introduced to the silicon layer in a comprehensive or in a locally restricted manner. Conventional methods, such as implantation or thermal diffusion, may also be used for the doping of the silicon layer.

Thin metal layers may also be used as the conductive layer provided that the metal is able to be through-oxidized, such as aluminum and titanium. In this case, the corresponding metal oxides result in the electric insulation of the conducting track and resistor configuration with respect to the remaining regions of the conductive layer.

The manner in which the conducting track and resistor configuration is produced in the conductive layer of a semiconductor element of the present invention may depend not only on the material and the condition of the initial substrate, but also on the component structure to be produced or the function of the semiconductor element. Accordingly, a plurality of variations may be used to realize the method of the present invention. It may be important for the conductive layer to be regionally through-oxidized so that at least one region of the conductive layer is electrically insulated by the oxidized regions with respect to the remaining regions of the conductive layer. The conducting track and resistor configuration is advantageously defined in the conductive layer using a masking layer that is produced and subsequently structured over the conductive layer. In this context, the regions of the conductive layer to be oxidized are exposed so that they are able to be through-oxidized during thermal oxidation.

### BRIEF DESCRIPTION OF THE DRAWINGS

FIG. 1 shows a cross section of a semiconductor element of the present invention in which a membrane is configured with a heat structure.

FIG. 2 shows the semiconductor element represented in FIG. 1 following removal of the masking layer.

FIG. 3 shows the semiconductor element represented in FIG. 1 configured as a gas sensor element.

FIG. 4 shows the semiconductor element represented in FIG. 2 configured as a gas sensor.

FIG. 5 shows a cross section of a semiconductor element configured as a flow sensor element.

### DETAILED DESCRIPTION OF EXAMPLE EMBODIMENTS

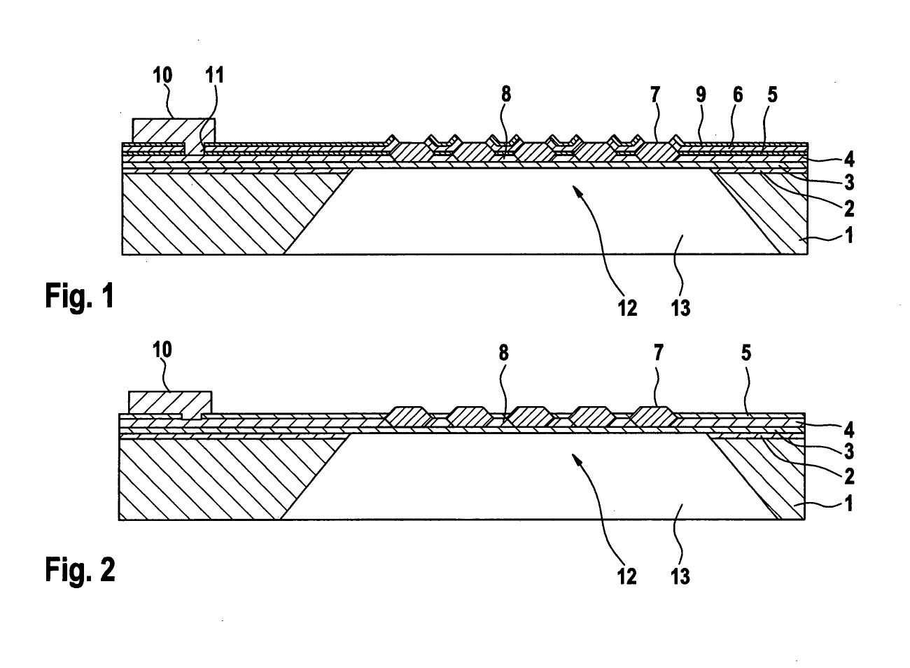

An oxidized silicon wafer 1 was used as the initial substrate for producing the semiconductor elements represented in FIGS. 1 through 4. A silicon nitride layer 3 and a subsequent polysilicon layer 4, which forms the conductive layer of each represented semiconductor element, were deposited on silicon oxide layer 2. This polysilicon layer 4 may be p- and/or n-doped locally or all over—based on the function of the semiconductor. Implantation or diffusion also enable regions having different doping materials and doping material concentrations to be produced. A possibly resulting stress in the component structure may be adjusted via suitable additional cover layers, e.g., of oxides, nitrides, SiC, etc.

The semiconductor elements represented in FIGS. 1 through 4 may also be produced on the basis of an SOI wafer. SOI wafers are provided with a monocrystalline silicon layer that is insulated by a silicon nitride layer Si₃N₄ and/or a silicon oxide layer SiO₂ with respect to the silicon substrate. When using an SOI wafer, the monocrystalline silicon layer is used as the conductive layer. It is treated in the same manner polysilicon layer 4, which is described below in greater detail.

A thin silicon oxide layer SiO₂ 5, on which a silicon nitride layer Si₃N₄ 6 was then deposited as a masking layer, was produced on polysilicon layer 4, e.g., via thermal oxidation. Masking layer 6 was structured in accordance with the conducting track and resistor configuration to be produced. In this context, the regions in polysilicon layer 4 to be oxidized were exposed. These exposed regions were oxidized during thermal oxidation, the oxidation conditions and in particular the duration being selected such that polysilicon layer 4 is completely through-oxidized. In this process, silicon nitride layer 3 is used as an oxidation stop layer. This oxidation step yielded oxidized regions 7 in polysilicon layer 4, which electrically insulate the conducting tracks with respect to the remaining regions of polysilicon layer 4. Silicon oxide layer 5 is primarily used for stress compensation underneath masking layer 6 and may be eliminated depending on the process requirements. During the oxidation step in which polysilicon layer 4 is regionally through-oxidized, an oxide layer 9, which is referred to as the reox layer, also resulted on the silicon nitride of masking layer 6.

The electrical connection between aluminum bondlands 10 and conducting tracks 8 formed in polysilicon layer 4 is created in the case of the semiconductor element represented in FIG. 1 via a contact opening 11, which is subsequently introduced in reox layer 9, masking layer 6, and silicon oxide layer 5. In the case of the semiconductor element represented in FIG. 2, reox layer 9 and masking layer 6 were removed before a contact opening 11 was introduced in silicon oxide layer 5.

Finally, membrane 12 was exposed in that, for example, a cavity 13 was etched into the wafer backside using KOH. In this manner, low heat dissipation was achieved in the region of the heat-conducting structure. Silicon nitride layer 3 is used as an etching stop layer when etching cavity 13. In this manner, membranes having a defined target thickness may be produced in a particularly effective manner. Therefore, silicon nitride layer 3 assumes the function of an oxidation stop layer during the local through-oxidizing of polysilicon layer 4 as well as the function of an etching stop layer during the etching of cavity 13. Moreover, the membrane stress may be adjusted via silicon nitride layer 3.

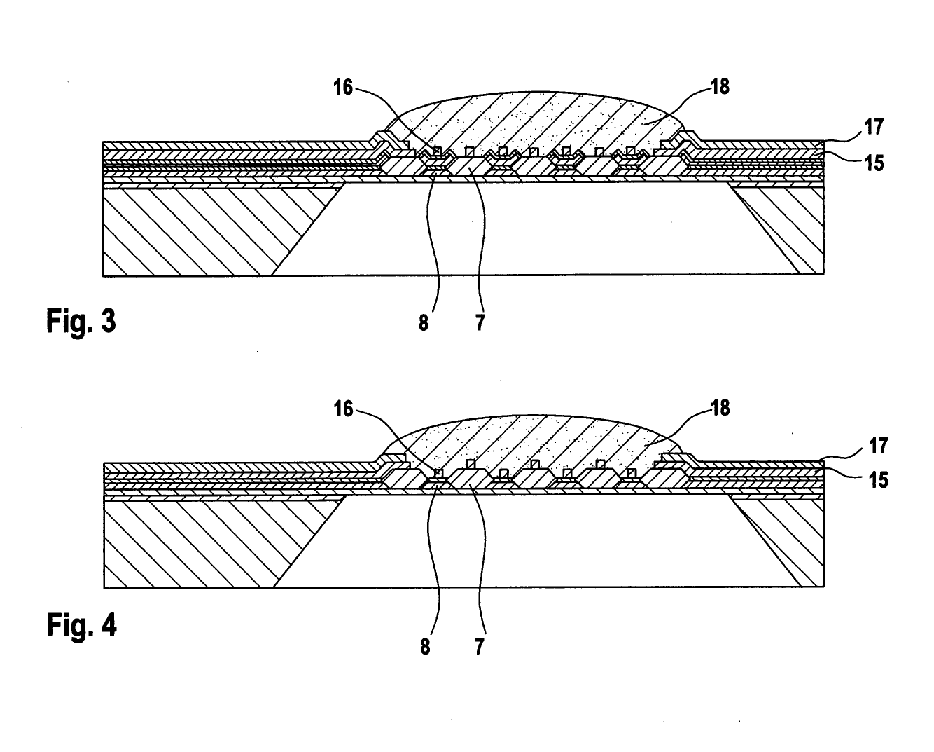

The semiconductor elements represented in FIGS. 1 and 2 may be configured for use in a gas sensor, which is shown in FIGS. 3 and 4. For this purpose, a platinum layer 15 was formed on membrane 12. Instead of the platinum layer, another metal layer could also have been produced. Individual Pt conducting tracks 16, which are situated on heat-conducting tracks 8 of membrane 12, were structured from this platinum layer 15. An insulating layer 17 of silicon oxide, silicon nitride, and/or silicon oxynitride, which was partially removed in the region of the heat-conducting structure above Pt conducting tracks 16, was deposited over platinum layer 15. Instead, a gas-sensitive layer 18 was applied on the heat-conducting structure and Pt conducting tracks 16. When acted upon by gas, the electrical resistance of this gas-sensitive layer 18 changes, which is recorded via Pt conducting tracks 16. The chemical reactiveness of the gas-sensitive layer may be increased as a result of a heating action via the heat-conducting structure.

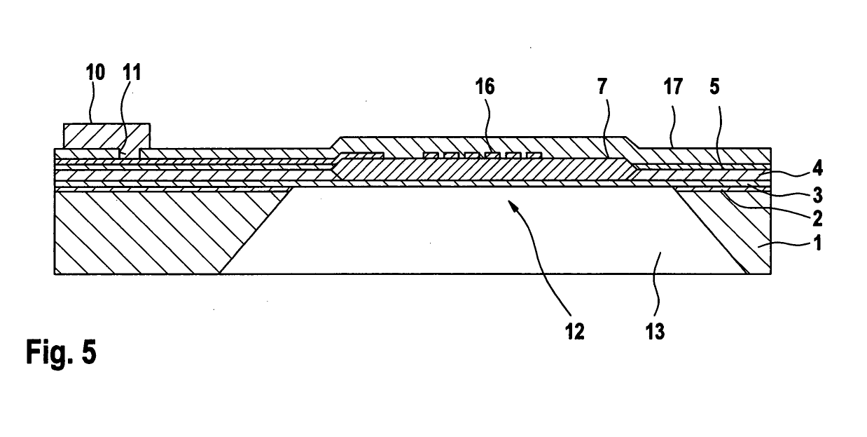

FIG. 5 shows a semiconductor element in which the reox layer and the oxidation mask have been removed and which is designed for use in a flow sensor. Pt conducting tracks 16 were also produced in this instance on an oxidized region 7 in membrane 12. The size of oxidized region 7 may be selected as desired. However, in this instance, insulation layer 17 extends over the entire semiconductor element surface with the exception of contact openings 11. Pt conducting tracks 16 are used in this instance for temperature generation and for measuring the temperature distribution in membrane 12. Since the symmetry of the temperature distribution is altered by a gas flow via membrane 12, conclusions regarding flow speed and flow direction may be made by determining the temperature distribution.

Finally, it should be mentioned that components having other functions, such as IR sources, Fresnel lenses, microfilters, thermopiles, etc., may also be produced using the method of the present invention for local oxidation of conductive layers.

### Reference Numerals

1 Silicon wafer
2 Silicon oxide layer
3 Silicon nitride layer—oxidation and etching stop layer
4 Polysilicon layer
5 Silicon oxide layer
6 Silicon nitride layer—masking layer/oxidation mask
7 Oxidized regions
8 Conducting track/heat-conducting track/structure
9 Reox layer
10 Aluminum bondlands
11 Contact opening
12 Membrane
13 Cavity
14 -
15 Platinum layer
16 Pt conducting track
17 Insulation layer
18 Gas-sensitive layer

1. A semiconductor element, comprising:
at least one conductive layer in which at least one of a conducting track and a resistor, is configured;
wherein the conductive layer-includes oxidized regions, and wherein the at least one of the conducting track and the resistor is electrically insulated, by the oxidized regions in the conductive layer, with respect to remaining regions of the conductive layer.

2. The semiconductor element as recited in claim 1, wherein the conductive layer is made of a semiconductive material, including one of germanium, SiGe, SiC, or diamond-like carbon.

3. The semiconductor element as recited in claim 1, wherein the conductive layer is made of monocrystalline or polycrystalline silicon.

4. The semiconductor element as recited in claim 3, wherein the conductive silicon layer is at least regionally at least one of p-doped and n-doped.

5. The semiconductor element as recited in claim 1, wherein the conductive layer is made of a metal, the metal including one of aluminum or titanium.

6. The semiconductor element as recited in claim 1, wherein the at least one of the conducting track and the resistor is at least partially protected by at least one insulation layer.

7. A method for producing a semiconductor element, comprising:
providing at least one conductive layer; and
forming at least one of a conducting track and a resistor by regionally through-oxidization so that at least one region of the conductive layer is electrically insulated by oxidized regions with respect to remaining regions of the conductive layer.

8. The method as recited in claim 7, further comprising:
producing a masking layer over the conductive layer;
structuring the masking layer to expose regions of the conductive layer to be oxidized; and
through-oxidizing the regions of the conductive layer during thermal oxidation.

9. The method as recited in claim 8, wherein the conductive layer is formed by a monocrystalline or polycrystalline silicon layer, and wherein the masking layer is a silicon nitride layer (Si₃N₄).

10. A method for producing a semiconductor element having a membrane, which includes a heat-conducting structure, comprising:
providing a substrate including an etching stop layer;
forming a conductive silicon layer over the etching stop layer, the conductive silicon layer including one of a monocrystalline polycrystalline silicon layer;
applying a masking layer over the conductive silicon layer;
structuring the masking layer according to the heat-conducting structure to be produced in the conductive silicon layer, and exposing surface regions of the conductive silicon layer; and
through-oxidizing the conductive silicon layer starting from the exposed surface regions so that the heat-conducting structure is electrically insulated with respect to remaining regions of the conductive silicon layer.

11. The method according to claim 10, wherein the substrate is one of a silicon substrate, a metal substrate, a glass substrate and a ceramic substrate.

12. The method as recited in claim 10, wherein the substrate is a silicon substrate, and wherein the method further comprises:
etching a cavity in the substrate starting from a side of the silicon substrate opposite the conductive silicon layer in a region of the heat-conducting structure, the etching stop layer limiting the etching.

13. The method as recited in claim 10, further comprising:
producing a plurality of conducting-track layers and resistor layers.
